(19) United States
(12) Patent Application Publication
(10) Pub. No.: US 2003/0049931 A1
(43) Pub. Date: Mar. 13, 2003

(54) Formation of refractory metal nitrides using chemisorption techniques

(75) Inventors: Jeong Soo Byun, Cupertino, CA (US); Lin Yin, Palo Alto, CA (US); Frederick C. Wu, Cupertino, CA (US); Ramanujapuram A. Srinivas, San Jose, CA (US); Avgerinos Gelatos, Redwood City, CA (US); Alfred W. Mak, Union City, CA (US); Mei Chang, Saratoga, CA (US); Moris Kori, Palo Alto, CA (US); Ashok K. Sinha, Palo Alto, CA (US)

Correspondence Address: APPLIED MATERIALS, INC., 2881 SCOTT BLVD. M/S 2061, SANTA CLARA, CA, 95050, US

(73) Assignee: APPLIED MATERIALS, INC.

(21) Appl. No.: 09/960,469

(22) Filed: Sep. 19, 2001

(51) Int. Cl. H01L 21/4763

(52) U.S. Cl. 438/649

(57) ABSTRACT

Refractory metal nitride layers for integrated circuit fabrication are described. The refractory metal nitride layer may be formed by sequentially chemisorbing alternating monolayers of a nitrogen-containing compound and a refractory metal compound onto a substrate. A composite refractory metal nitride layer is also described. The composite refractory metal nitride layer may be formed by sequentially chemisorbing monolayers of a nitrogen-containing compound and two or more refractory metal compounds onto a substrate.

### BACKGROUND OF THE DISCLOSURE

1. Field of the Invention

The present invention relates to the formation of refractory metal nitride layers and, more particularly to refractory metal nitride layers formed using chemisorption techniques.

2. Description of the Background Art

In the manufacture of integrated circuits, barrier layers are often used to inhibit the diffusion of metals and other impurities into regions underlying such barrier layers. These underlying regions may include transistor gates, capacitor dielectric, semiconductor substrates, metal lines, as well as many other structures that appear in integrated circuits.

Compounds of refractory metals such as, for example, nitrides, borides, and carbides have been suggested as diffusion barriers because of their chemical inertness and low resistivities (e.g., resistivities typically less than about 200 μΩ-cm). In particular, nitrides such as, for example, titanium nitride (TiN) have been suggested for use as a barrier material since layers formed thereof generally have low resistivities (e.g., resistivities less than about 150 μΩ-cm).

Reliably producing sub-half micron and smaller features is one of the key technologies for the next generation of very large scale integration (VLSI) as well as ultra large scale integrated (ULSI) circuits. In particular, as the fringes of circuit technology are pressed, the shrinking dimensions of interconnect features in VLSI and ULSI technology has placed additional demands on processing capabilities. For example, multilevel interconnect features require careful processing of high aspect ratio (e.g., the ratio of the feature height to the feature width) structures, such as vias, lines and contacts. Reliable formation of these features is very important to the continued effort to increase circuit density and quality of integrated circuits.

As circuit densities increase, the widths of vias, lines, and contacts may decrease to sub-micron dimensions (e.g., less than 0.25 micrometers or less), whereas the thickness of the dielectric material layers between such structures typically remains substantially constant, increasing the aspect ratios for such features. Many traditional deposition processes have difficulty filling sub-micron structures where the aspect ratio exceeds 4:1, and especially where the aspect ratio exceeds 10:1.

FIGS. 1A-B illustrate the possible consequences of material layer deposition in a high aspect ratio feature 6 on a substrate 1. The high aspect ratio feature 6 may be any opening such as a space formed between adjacent features 2, a contact, a via, or a trench defined in a layer 2. As shown in FIG. 1A, a material layer 11 that is deposited using conventional deposition techniques tends to be deposited on the top edges 6T of the feature 6 at a higher rate than at the bottom 6B or sides 6S thereof creating an overhang. This overhang or excess deposition of material is sometimes referred to as crowning. Such excess material continues to build up on the top edges 6T of the feature 6, until the opening is closed off by the deposited material 11, forming a void 14 therein. Additionally, as shown in FIG. 1B, a seam 8 may be formed when a material layer 11 deposited on both sides 6S of the opening 6 merges. The presence of either voids or seams may result in unreliable integrated circuit performance.

Therefore, a need exists for a method of depositing a material layer on a substrate to provide void-free and seam-free filling of high aspect ratio openings.

### SUMMARY OF THE INVENTION

Refractory metal nitride layers for integrated circuit fabrication are provided. In one embodiment, the refractory metal nitride layer comprises one refractory metal. The refractory metal nitride layer may be formed by sequentially chemisorbing alternating monolayers of a nitrogen-containing compound and a refractory metal compound onto a substrate.

In an alternate embodiment, a composite refractory metal nitride layer is formed. The composite refractory metal nitride layer comprises two or more refractory metals. The composite refractory metal nitride layer may be formed by sequentially chemisorbing monolayers of a nitrogen-containing compound and two or more refractory metal compounds onto a substrate.

The refractory metal nitride layer is compatible with integrated circuit fabrication processes. In one integrated circuit fabrication process, a refractory metal nitride layer is formed on a refractory metal layer deposited on a substrate. The refractory metal nitride layer comprises one refractory metal. The refractory metal nitride layer is formed by sequentially chemisorbing alternating monolayers of a nitrogen-containing compound and one refractory metal compound on a substrate. Thereafter, one or more metal layers are deposited on the refractory metal nitride layer to form an interconnect structure.

In another integrated circuit fabrication process, the refractory metal nitride layer that is formed on the refractory metal layer has a composite structure. The composite refractory metal nitride layer comprises two or more refractory metals. The refractory metal nitride layer is formed by sequentially chemisorbing monolayers of a nitrogen-containing compound and two or more refractory metal compounds on a substrate. Thereafter, one or more metal layers are deposited on the composite refractory metal nitride layer to form an interconnect structure.

### BRIEF DESCRIPTION OF THE DRAWINGS

The teachings of the present invention can be readily understood by considering the following detailed description in conjunction with the accompanying drawings, in which:

FIGS. 1A-1B are cross-sectional views of possible deposition results for high aspect ratio features filled using conventional prior art deposition processes;

FIG. 2 depicts a schematic illustration of an apparatus that can be used for the practice of embodiments described herein;

FIG. 3 depicts a schematic cross-sectional view of a sputtering type physical vapor deposition (PVD) chamber;

FIG. 4 depicts a schematic cross-sectional view of a chemical vapor deposition (CVD) chamber;

FIG. 5 depicts a schematic illustration of an atomic layer deposition chamber;

FIGS. 6A-6C depict cross-sectional views of a substrate at different stages of integrated circuit fabrication incorporating a refractory metal nitride barrier layer formed using a sequential chemisorption process;

FIGS. 7A-7D depict cross-sectional views of a substrate undergoing a sequential chemisorption process of a nitrogen-containing compound and a refractory metal compound to form a refractory metal nitride layer;

FIGS. 8A-8C depict cross-sectional views of a substrate undergoing a sequential chemisorption process of a nitrogen-containing compound and two or more refractory metal compounds gas to form a composite refractory metal nitride layer; and

FIGS. 9A-9G depict cross-sectional views of a capacitive memory cell at different stages of integrated circuit fabrication incorporating a refractory metal nitride electrode formed using a sequential chemisorption process.

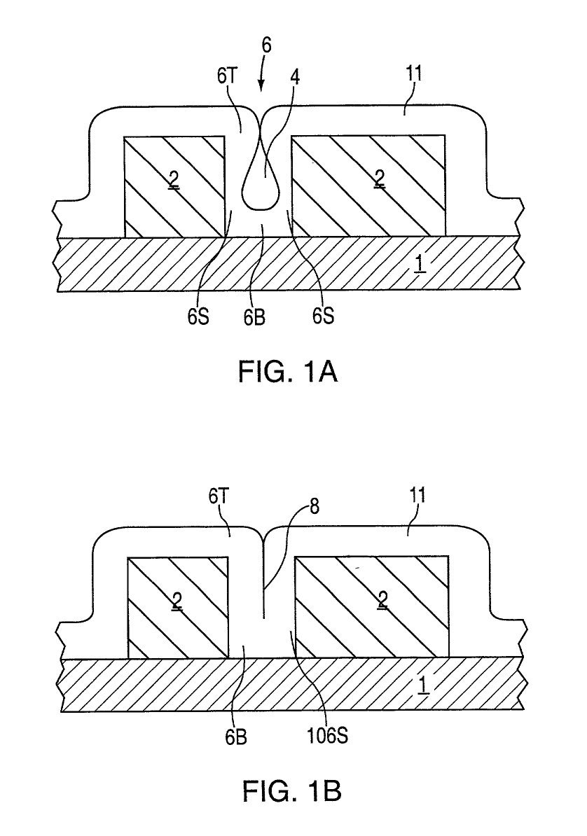

### DETAILED DESCRIPTION

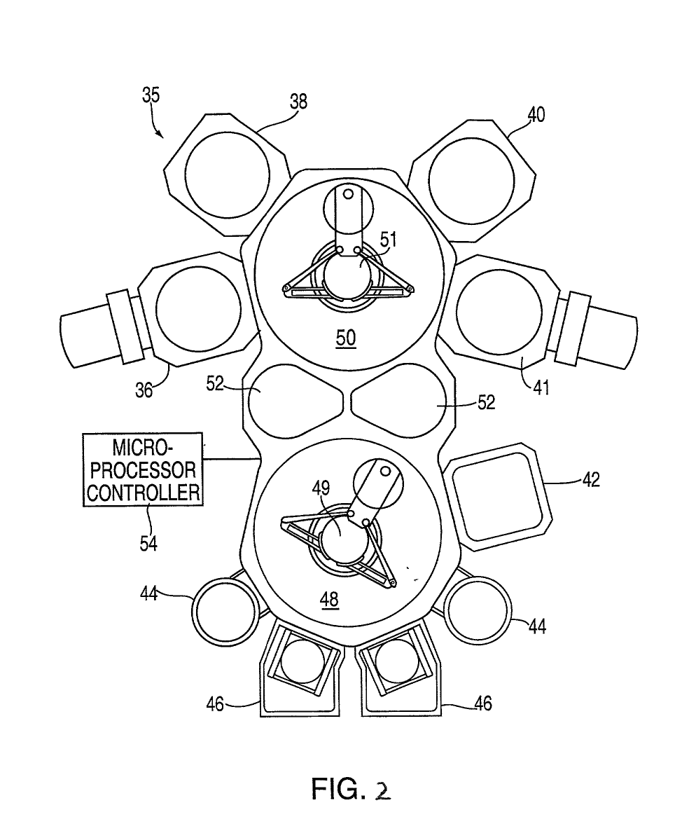

FIG. 2 is a schematic representation of a wafer processing system 35 that can be used to perform integrated circuit fabrication in accordance with embodiments described herein. The wafer processing system 35 typically comprises process chambers 36, 38, 40, 41, degas chambers 44, load-lock chambers 46, transfer chambers 48, 50, pass-through chambers 52, a microprocessor controller 54, along with other hardware components such as power supplies (not shown) and vacuum pumps (not shown). An example of such a wafer processing system 35 is an ENDURA® System, commercially available from Applied Materials, Inc., Santa Clara, Calif.

Details of the wafer processing system 35 are described in commonly assigned U.S. Pat. No. 5,186,718, entitled “Staged-Vacuum Substrate Processing System and Method”, issued on Feb. 16, 1993, and is hereby incorporated by reference. The salient features of the wafer processing system 35 are briefly described below.

The wafer processing system 35 includes two transfer chambers 48, 50 each containing a transfer robot 49, 51. The transfer chambers 48, 50 are separated one from the other by pass-through chambers 52.

Transfer chamber 48 is coupled to load-lock chambers 46, degas chambers 44, pre-clean chamber 42, and pass-through chambers 52. Substrates (not shown) are loaded into the wafer processing system 35 through load-lock chambers 46. Thereafter, the substrates are sequentially degassed and cleaned in degas chambers 44 and the pre-clean chamber 42, respectively. The transfer robot 48 moves the substrates between the degas chambers 44 and the pre-clean chamber 42.

Transfer chamber 50 is coupled to a cluster of process chambers 36, 38, 40, 41. The cleaned substrates are moved from transfer chamber 48 into transfer chamber 50 via pass-through chambers 52. Thereafter, transfer robot 51 moves the substrates between one or more of the process chambers 36, 38, 40, 41.

The process chambers 36, 38, 40, 41 are used to perform various integrated circuit fabrication sequences. For example, process chambers 36, 38, 40, 41 may include physical vapor deposition (PVD) chambers, ionized metal plasma physical vapor deposition (IMP PVD) chambers, chemical vapor deposition (CVD) chambers, atomic layer deposition chambers (ALD), and antireflective coating (ARC) chambers, among others.

FIG. 3 depicts a schematic cross-sectional view of a sputtering-type physical vapor deposition (PVD) process chamber 36. The sputtering-type physical vapor deposition (PVD) process chamber 36 can be used to perform integrated circuit fabrication in accordance with the embodiments described herein. An example of such a PVD process chamber 36 is an IMP VECTRA™ chamber, commercially available from Applied Materials, Inc., Santa Clara, Calif.

The PVD chamber 36 is coupled to a gas source 104, a pump system 106 and a target power source 108. The PVD chamber 36 encloses a target 110, a substrate 120 positioned on a vertically movable pedestal 112, and a shield 114 enclosing a reaction zone 118. A lift mechanism 116 is coupled to the pedestal 112 to position the pedestal 112 relative to the target 110.

The gas source 104 supplies a process gas into the PVD chamber 36. The process gas generally includes argon (Ar) or some other inert gas. The pump system 106 controls the pressure within the PVD chamber 36.

The target 110 is typically suspended from the top of the PVD chamber 36. The target 110 includes a material that is sputtered during operation of the wafer processing system 135. Although the target 110 may comprise, as a material to be deposited, an insulator or semiconductor, the target 110 generally comprises a metal. For example, the target 110 may be formed of titanium (Ti), tantalum (Ta), and combinations thereof as well as other materials known in the art.

The pedestal 112 supports the substrate 120 within the PVD chamber 36. The pedestal 112 is generally disposed at a fixed distance from the target 110 during processing. However, the distance between the target 110 and the substrate 120 may also be varied during processing. The pedestal 112 is supported by the lift mechanism 116, which moves the pedestal along a range of vertical motion within the PVD chamber 36.

The target power source 108 is used to infuse the process gas with energy and may comprise a DC source, a radio frequency (RF) source, or a DC-pulsed source. Applying either DC or RF power to the process gas creates an electric field in the reaction zone 118. The electric field ionizes the process gas in the reaction zone 118 to form a plasma comprising process gas ions, electrons, and process gas atoms (neutrals). Additionally, the electric field accelerates the process gas ions toward the target 110, for sputtering target particles from the target 110. When electrons in the plasma collide with the sputtered target particles, such target particles become ionized.

The process chamber 36 configuration enables deposition of sputtered and ionized target particles from the target 110 onto the substrate 120 to form a film 122 thereon. The shield 114 confines the sputtered particles and non-reactant gas in a reaction zone within the process chamber 36. As such, the shield 114 prevents deposition of target particles in unwanted locations, for example, beneath the pedestal 112 or behind the target 110.

The process chamber 36 may comprise additional components for improving the deposition of sputtered particles onto the substrate 120. For example, the process chamber 36 may include a bias power source 124 for biasing the substrate 120. The bias power source 124 is coupled to the pedestal 112 for controlling material layer deposition onto the substrate 120. The bias power source 124 is typically an AC source having a frequency of, for example, about 400 kHz.

When the bias power from the power source 124 is applied to the substrate 120, electrons in the plasma accumulate to the substrate 120, creating a negative DC offset on the substrate 120 and the pedestal 112. The bias power applied to the substrate 120 attracts sputtered target particles that become ionized. These ionized target particles are generally attracted to the substrate 120 in a direction that is substantially perpendicular thereto. As such, the bias power source 124 enhances the deposition of target particles onto the substrate 120.

The process chamber 36 may also comprise a magnet 126 or magnetic sub-assembly positioned behind the target 110 for creating a magnetic field proximate to the target 110. The process chamber 36 may also comprise a coil 130 disposed within the shield 114 between the target 110 and the substrate 120. The coil 130 may comprise either a single-turn coil or a multi-turn coil that, when energized, ionizes the sputtered particles. This process is known as Ion Metal Plasma (IMP) deposition. The coil 130 is generally coupled to an AC source 132 having a frequency of, for example, about 2 MHz.

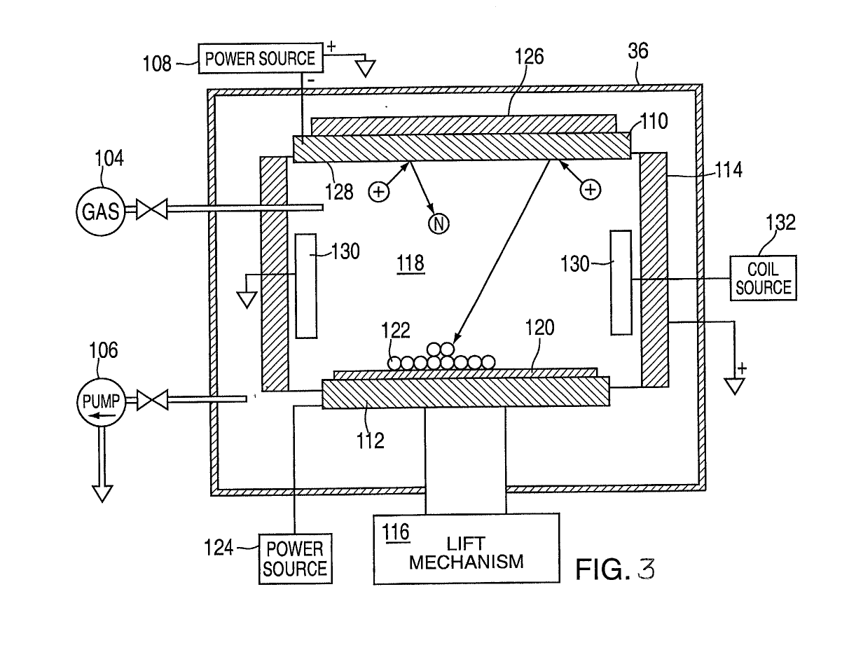

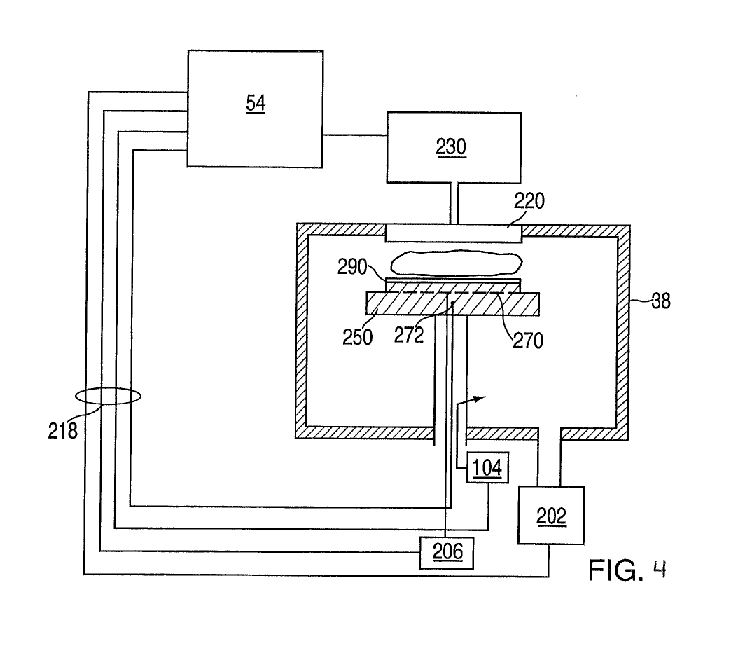

FIG. 4 depicts a schematic cross-sectional view of a chemical vapor deposition (CVD) process chamber 38. The chemical vapor deposition (CVD) process chamber 38 can be used to perform integrated circuit fabrication in accordance with the embodiments described herein. Examples of such CVD process chambers 38 include TXZ™ chambers, WXZ™ chambers, DXZ™ chambers, and PRECISION 5000® chambers, commercially available from Applied Materials, Inc., Santa Clara, Calif.

The CVD process chamber 38 generally houses a wafer support pedestal 250, which is used to support a substrate 290. The wafer support pedestal 250 can typically be moved in a vertical direction inside the CVD process chamber 38 using a displacement mechanism (not shown).

Depending on the specific CVD process, the substrate 290 can be heated to some desired temperature prior to or during deposition. For example, the wafer support pedestal 250 is heated by an embedded heater element 270. The wafer support pedestal 250 may be resistively heated by applying an electric current from an AC power supply 206 to the heater element 270. The substrate 290 is, in turn, heated by the pedestal 250.

A temperature sensor 272, such as a thermocouple, is also embedded in the wafer support pedestal 250 to monitor the temperature of the pedestal 250 in a conventional manner. The measured temperature is used in a feedback loop to control the AC power supply 206 for the heating element 270, such that the substrate temperature can be maintained or controlled at a desired temperature which is suitable for the particular process application. The wafer support pedestal 250 is optionally heated using radiant heat (not shown).

A vacuum pump 202 is used to evacuate the CVD process chamber 38 and to maintain the proper gas flows and pressures inside such chamber 38. A showerhead 220, through which process gases are introduced into the chamber 38, is located above the wafer support pedestal 250. The showerhead 220 is connected to a gas panel 230 that controls and supplies various gases provided to the chamber 38.

Proper control and regulation of the gas flows through the gas panel 230 is performed by mass flow controllers (not shown) and a microprocessor controller 54 (FIG. 2). The showerhead 220 allows process gases from the gas panel 230 to be uniformly introduced and distributed in the CVD process chamber 38.

The CVD process chamber 38 may comprise additional components for enhancing layer deposition on the substrate 290. For example, the showerhead 220 and wafer support pedestal 250 may also form a pair of spaced apart electrodes. When an electric field is generated between these electrodes, the process gases introduced into the chamber 38 are ignited into a plasma.

Typically, the electric field is generated by coupling the wafer support pedestal 250 to a source of radio frequency (RF) power (not shown) through a matching network (not shown). Alternatively, the RF power source and matching network may be coupled to the showerhead 220, or coupled to both the showerhead 220 and the wafer support pedestal 250.

Plasma enhanced chemical vapor deposition (PECVD) techniques promote excitation and/or disassociation of the reactant gases by the application of the electric field to the reaction zone near the substrate surface, creating a plasma of reactive species. The reactivity of the species in the plasma reduces the energy required for a chemical reaction to take place, in effect lowering the required temperature for such PECVD processes.

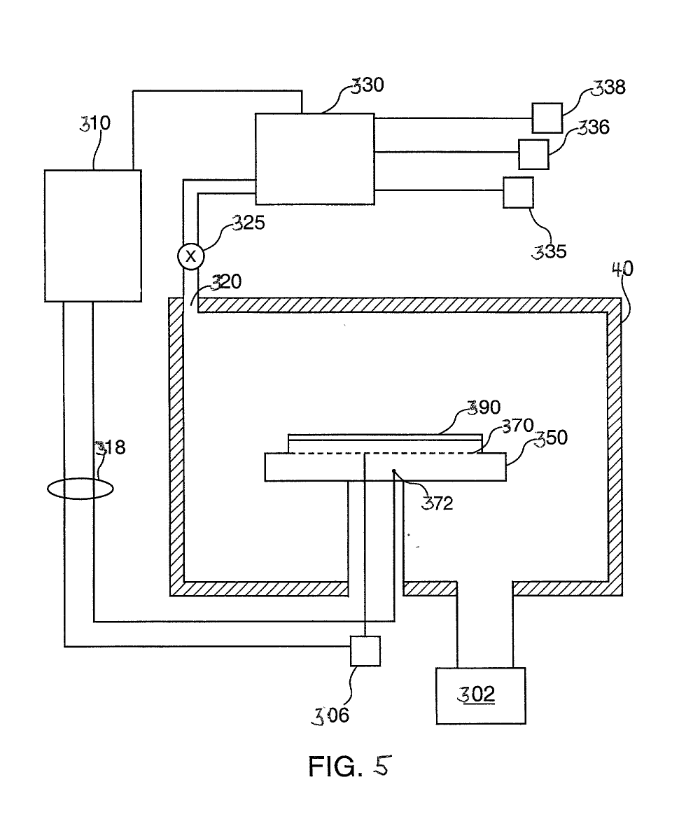

FIG. 5 depicts a schematic cross-sectional view of an atomic layer deposition (ALD) process chamber 40. The atomic layer deposition (ALD) process chamber 40 generally houses a support pedestal 350, which is used to support a substrate such as a semiconductor wafer 390 within the process chamber 40. Depending on the specific process, the semiconductor wafer 390 can be heated to some desired temperature prior to layer formation.

In chamber 40, the wafer support pedestal 350 is heated by an embedded heater 370. For example, the pedestal 350 may be resistively heated by applying an electric current from an AC power supply 306 to the heater element 370. The wafer 390 is, in turn, heated by the pedestal 350, and can be maintained within a desired process temperature range of, for example, about 20° C. to about 500° C.

A temperature sensor 372, such as a thermocouple, is also embedded in the wafer support pedestal 350 to monitor the temperature of the pedestal 350 in a conventional manner. For example, the measured temperature may be used in a feedback loop to control the electric current applied to the heater element 370 by the power supply 306, such that the wafer temperature can be maintained or controlled at a desired temperature that is suitable for the particular process application. The pedestal 350 is optionally heated using radiant heat (not shown).

A vacuum pump 302 is used to evacuate process gases from the process chamber 40 and to help maintain the desired pressure inside the chamber 40. An orifice 320 is used to introduce process gases into the process chamber 40. The dimensions of the orifice 320 are variable and typically depend on the size of the process chamber 40.

The orifice 320 is coupled to a gas panel 330 via a valve 325. The gas panel 330 provides process gases from two or more gas sources 335, 336 to the process chamber 40 through orifice 320 and valve 325. The gas panel 330 also provides a purge gas from a purge gas source 338 to the process chamber 40 through orifice 320 and valve 325.

Referring to FIG. 2, the PVD process chamber 36, the CVD process chamber 38, and the ALD process chamber 40, as described above are controlled by a microprocessor controller 54. The microprocessor controller 54 may be one of any form of general purpose computer processor that can be used in an industrial setting for controlling various chambers and sub-processors. The computer processor may use any suitable memory, such as random access memory, read only memory, floppy disk drive, hard disk, or other form of digital storage, local or remote. Various support circuits may be coupled to the microprocessor controller 54 for supporting the processor in a conventional manner. Software routines as required may be stored in the memory or executed by a second microprocessor controller that is remotely located.

The software routines are executed after the substrate is positioned in one of the process chambers 36, 38, 40, 41. The software routine, when executed, transforms the general purpose computer into a specific process computer that controls the chamber operation so that the deposition process is performed. Alternatively, the embodiments described herein may be performed in hardware, as an application specific integrated circuit or other type of hardware implementation, or a combination of software and hardware.

Integrated Circuit Fabrication Processes

A. Interconnect Fabrication

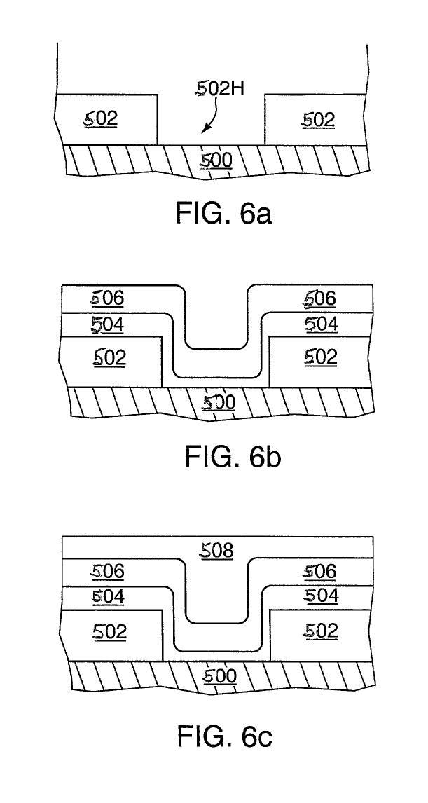

In FIGS. 6A-6C, interconnects are formed by filling high aspect ratio structures with one or more barrier layers followed by deposition of one or more metal layers thereon. The barrier layers may comprise for example, titanium (Ti), titanium nitride (TiN), tantalum (Ta), tantalum nitride (TaNₓ), tungsten (W), or tungsten nitride (WNₓ), among others. The one or more barrier layers may be conformably deposited on the substrate using atomic layer deposition (ALD). The one or more metal layers may comprise tungsten (W), aluminum (Al) and copper (Cu), among others.

The barrier layer may be formed on a refractory metal layer deposited on the substrate. In one embodiment, the refractory metal layer may be conformably deposited on the substrate using physical vapor deposition (PVD) or chemical vapor deposition (CVD).

In general, the following deposition process parameters can be used to conformably form the refractory metal layer using a PVD process chamber similar to the one depicted in FIG. 3. The process parameters range from a wafer temperature of about 20° C. to about 300° C., a chamber pressure of about 1.0 torr to about 100 torr, a DC power of about 1 kilowatt to about 20 kilowatts, and a bias power of about 1 watt to about 500 watts.

Also, an inert gas such as helium (He) or argon (Ar) may be provided to the PVD deposition chamber to maintain the chamber at a desired chamber pressure. The inert gas may be provided to the deposition chamber at a flow rate in a range of about 100 sccm to about 5000 sccm.

The above PVD process parameters provide a deposition rate for the one or more barrier layers in a range of about 50 Å/min to about 500 521 /min.

Using CVD techniques, the refractory metal layer may be formed from a titanium or tantalum precursor. The titanium or tantalum precursor may be selected from tetrakis(dimethylamido)titanium (TDMAT), pentakis(dimethylamido) tantalum (PDMAT), tetrakis(diethylamido)titanium (TDEAT), tungsten hexacarbonyl (W(CO)₆), tungsten hexachloride (WCl₆), tetrakisdiethylamido)titanium (TDEAT), and pentakisdiethylamido)tantalum (PDEAT), among others.

Carrier gases such as hydrogen (H₂), helium (He), argon (Ar), and nitrogen (N₂), among others may be mixed with the titanium or tantalum precursors.

In general, the following process parameters can be used to form the refractory metal layer using CVD techniques in a process chamber similar to that shown in FIG. 4. The process parameters range from a wafer temperature of less than about 450° C., a chamber pressure of about 1 torr to about 10 torr, a tantalum or titanium precursor flow rate of about 50 sccm to about 7000 sccm, and a carrier gas flow rate of about 100 sccm to about 1 slm. The above process parameters typically provide a deposition rate for the CVD deposited one or more barrier layers in a range of about 10 Å/min. to about 200 Å/min.

Details of ALD processes for forming refractory metal nitride barrier layers are described in commonly assigned U.S. patent application Ser. No. 09/754,230, entitled “Method of Forming Refractory Metal Nitride Layers Using Chemisorption Techniques”, filed on Jan. 3, 2001;and U.S. patent application Ser. No. 09/885,609, entitled “Using Atomic Layer Deposition Techniques to Form a Composite/Multiple Film Stack of TiN and W as a Cu Barrier Layer”, filed on Jun. 20, 2001, is hereby incorporated by reference.

FIGS. 6A-6C illustrate one preferred embodiment of refractory metal nitride layer formation for fabrication of an interconnect structure. In general, the substrate 500 refers to any workpiece upon which film processing is performed, and a substrate structure 550 is used to generally denote the substrate 500 as well as other material layers formed on the substrate 500. Depending on the specific stage of processing, the substrate 500 may be a silicon semiconductor wafer, or other material layers which have been formed on the wafer. FIG. 6A, for example, shows a cross-sectional view of a substrate structure 550, having a material layer 502 thereon. In this particular illustration, the material layer 502 may be an oxide (e.g. silicon dioxide). The material layer 502 has been conventionally formed and patterned to provide contact holes 502H extending to the top surface 500T of the substrate 500.

FIG. 6B shows a refractory metal nitride layer 504 conformally formed on the substrate structure 550. The refractory metal nitride layer 504 is formed by chemisorbing monolayers of a nitrogen-based compound and at least one refractory metal compound on a substrate structure 550. The monolayers are chemisorbed by sequentially providing a nitrogen-based compound and one or more refractory metal compounds to a process chamber, such as ALD process chamber 36 shown in FIG. 5.

For TiN and or TaN layer ALD process chamber shown in FIG. 5 may be modified with for example heaters (not shown) positioned adjacent to the precursor gas lines to maintain vaporization of the precursor materials. In addition, the precursor gases may be mixed with one or more inert gases to provide a flow of precursor material to the ALD chamber.

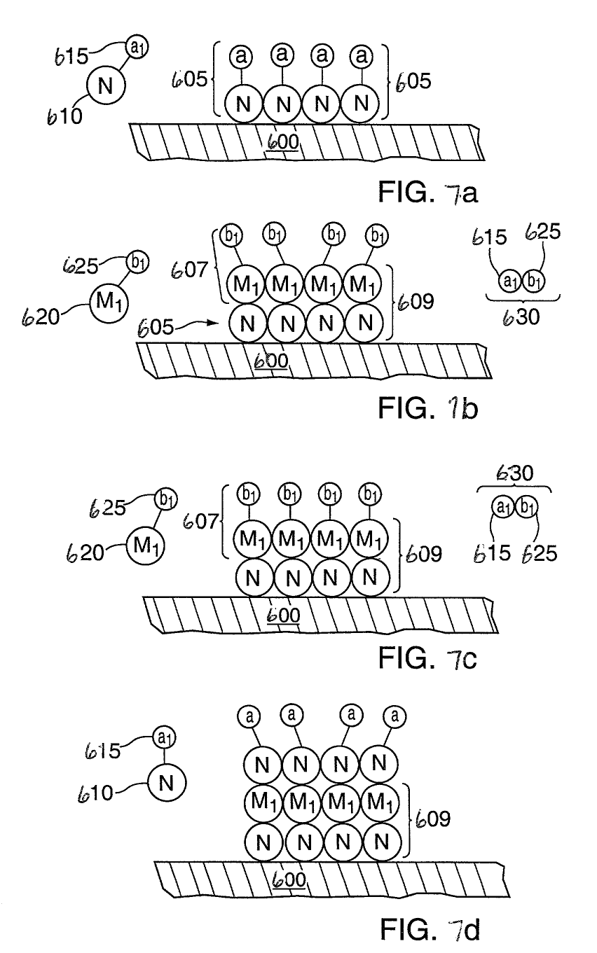

Monolayers of a nitrogen-based compound and one refractory metal compound are alternately chemisorbed on a substrate 600 as shown in FIGS. 7A-7D. FIG. 7A depicts a cross-sectional view of a substrate 600, which may be in a stage of integrated circuit fabrication. A monolayer of a nitrogen-based compound 605 is chemisorbed on the substrate 600 by introducing a pulse of a nitrogen-based gas into a process chamber similar to that shown in FIG. 5. The nitrogen-based compound typically combines nitrogen (N) atoms 610 with one or more reactive species a 615. During refractory metal nitride layer formation, the reactive species a 615 form by-products that are transported from the substrate surface by the vacuum system.

Chemisorption processes used to absorb the monolayer of the nitrogen-based compound 605 are self-limiting, in that only one monolayer may be chemisorbed onto the substrate 600 surface during a given pulse. Only one monolayer of the nitrogen-based compound may be chemisorbed on the substrate because the substrate has a limited surface area. This limited surface area provides a finite number of sites for chemisorbing the nitrogen-based compound. Once the finite number of sites are occupied by the nitrogen-based compound, further chemisorption of any nitrogen-based compound will be blocked.

Suitable nitrogen-based compounds may include, for example ammonia (NH₃), hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), as well as combinations thereof.

After the monolayer of the nitrogen-based compound is chemisorbed onto the substrate 600, excess nitrogen-based compound is removed from the process chamber by introducing a pulse of a purge gas thereto. Purge gases such as, for example helium (He), argon (Ar), nitrogen (N₂), and hydrogen (H₂), among others may be used.

After the process chamber has been purged, a pulse of one refractory metal compound is introduced into the process chamber. Referring to FIG. 7B, a monolayer of the refractory metal compound 607 is chemisorbed on the monolayer of hydrazine-based compound 605. The refractory metal compound typically combines refractory metal atoms M 620 with one or more reactive species b 625.

The chemisorbed monolayer of the refractory metal compound 607 reacts with the monolayer of nitrogen-based compound 605 to form a refractory metal nitride layer 609, as shown in FIG. 7C. The reactive species a 615 and b 625 form by-products ab 630 that are transported from the substrate surface by the vacuum system. The reaction of the refractory metal compound 607 with the nitrogen-based compound 605 is self-limited, since only one monolayer of the nitrogen-based compound was chemisorbed onto the substrate surface.

The refractory metal compound may include refractory metals such as, for example, titanium (Ti), tungsten (W), and tantalum (Ta), among others combined with reactive species such as, for example chlorine (Cl), fluorine (F), bromine (Br), and iodine (I). Titanium tetrachloride (TiCl₄), tungsten hexafluoride (WF₆), tantalum pentachloride (TaCl₅), titanium iodide (Til₄), titanium bromide (TiBr₄), among others may be used as the refractory metal compound. Suitable refractory metal compounds may also include metal organic compounds such as, for example, tetrakis(dimethylamido)titanium (TDMAT), pentakis(dimethylamido) tantalum (PDMAT), tetrakis(diethylamido)titanium (TDEAT), tungsten hexacarbonyl (W(CO)₆), tungsten hexachloride (WCl₆), tetrakisdiethylamido)titanium (TDEAT), and pentakisdiethylamido)tantalum (PDEAT), among others.

After the monolayer of the refractory metal compound is chemisorbed on the monolayer of nitrogen-based compound 605, any excess refractory metal compound is removed from the process chamber by introducing another pulse of the purge gas therein. Thereafter, as shown in FIG. 7D, the refractory metal nitride layer deposition sequence of alternating monolayers of the nitrogen-based compound and the refractory metal compound are repeated until a desired refractory metal nitride layer 609 thickness is achieved.

In FIGS. 7A-7D, refractory metal nitride layer formation is depicted as starting with the chemisorption of a monolayer of a nitrogen-based compound on the substrate followed by a monolayer of a refractory metal compound. Alternatively, the nitride layer formation may start with the chemisorption of a monolayer of a refractory metal compound on the substrate followed by a monolayer of the nitrogen-based compound.

The pulse time for each pulse of the nitrogen-based compound, the refractory metal compound, and the purge gas is variable and depends on the volume capacity of the deposition chamber as well as the vacuum system coupled thereto. Similarly, the time between each pulse is also variable and depends on the volume capacity of the process chamber as well as the vacuum system coupled thereto.

In general, the alternating monolayers may be chemisorbed at a substrate temperature between about 20° C. and 1000° C., and a chamber pressure less than about 100 torr. A pulse time of less than about 5 seconds for nitrogen-based compounds, and a pulse time of less than about 2 seconds for the refractory metal compounds are typically sufficient to chemisorb the alternating monolayers that comprise the refractory metal nitride layer on the substrate. A pulse time of less than about 2 seconds for the purge gas is typically sufficient to remove the reaction by-products as well as any residual materials remaining in the process chamber.

Referring to FIG. 6C, after the formation of the refractory metal nitride layer 504, a contact layer 506 may be formed thereon to complete the interconnect structure. The contact layer 506 is preferably selected from the group of aluminum (Al), copper (Cu), tungsten (W), and combinations thereof. Details of ALD processes for forming metal layers are described in commonly assigned U.S. patent application entitled, “Bifurcated Deposition Process for Depositing Refractory Metal Layer Employing Atomic Layer Deposition and Chemical Vapor Deposition, filed Jun. 28, 2000, Ser No. 09/605,596; U.S. patent application entitled, “Methods and Apparatus for Depositing Refractory Metal Layers Employing Sequential Deposition Techniques to Form Nucleation Layers”, filed Oct. 3, 2000, Ser No 09/678,266; and U.S. Pat. No. 6,099,904 Low Resitivity W Using B2H6 Nucleation Step, issued Aug. 8, 2000; which are incorporated by reference.

The contact layer 506 may be formed using atomic layer deposition combined with chemical vapor deposition (CVD). For example, a tungsten nucleation layer/ tungsten bulk layer may be deposited using tungsten hexafluoride (WF₆).

A nucleation layer of tungsten of a tungsten-based compound may be chemisorbed on a substrate. A nucleation layer of tungsten is chemisorbed on the substrate by introducing a pulse of a tungsten-based gas into a process chamber similar to that shown in FIG. 5. The tungsten-based compound typically combines tungsten (W) atoms with one or more reactive species a. During tungsten nucleation layer formation, the reactive species a form byproducts that are transported from the substrate surface by the vacuum system.

Chemisorption processes used to absorb the layer of the tungsten-based compound are self-limiting, in that predetermined thicknesses may be chemisorbed onto the substrate surface during a given pulse. Only predetermined thicknesses of the tungsten-based compound may be chemisorbed on the substrate because the substrate has a limited surface area. This limited surface area provides a finite number of sites for chemisorbing the tungsten-based compound. Once the finite number of sites are occupied by the tungsten-based compound, further chemisorption of any tungsten-based compound will be blocked.

Typically, thicknesses of less than about 100 Å may be obtained per absorption cycle. Additionally, smoother films with conformal step coverage are obtained in high aspect ratio structures (height:width ratios greater than about 4:1).

Suitable tungsten-based compounds may include, for example tungsten hexafluoride (WF₆), and tungsten carbonyl (W(CO)₆), among others. After a first thickness of the tungsten-based compound is chemisorbed onto the substrate, excess tungsten-based compound is removed from the process chamber by introducing a pulse of a purge gas thereto. Purge gases such as, for example helium (He), argon (Ar), nitrogen (N₂), and hydrogen (H₂), among others may be used.

After the process chamber has been purged, a pulse of a reducing gas is introduced into the process chamber. The reducing gas reacts with the tungsten-based compound. The reactive species a and b form by-products ab that are transported from the substrate surface by the vacuum system.

Suitable reducing gases may include for example, silane (SiH₄), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇), and decaborane (B₁₀H₃₀), among others.

After the reducing gas reacts with the tungsten-based compound excess reducing gas is removed from the process chamber by introducing another pulse of the purge gas therein. Thereafter, the tungsten nucleation layer deposition sequence of alternating the tungsten-based compound and the reducing gas are repeated until a desired tungsten nucleation layer thickness is achieved.

The pulse time for each pulse of the tungsten-based compound, the reducing gas, and the purge gas is variable and depends on the volume capacity of the deposition chamber as well as the vacuum system coupled thereto. Similarly, the time between each pulse is also variable and depends on the volume capacity of the process chamber as well as the vacuum system coupled thereto.

In general, the tungsten nucleation layer may be chemisorbed at a substrate temperature between about 20° C. and 1000° C., and a chamber pressure less than about 100 torr. A pulse time of less than about 5 seconds for tungsten-based compounds, and a pulse time of less than about 2 seconds for the reducing gas are typically sufficient to form the tungsten nucleation layer on the substrate. A pulse time of less than about 2 seconds for the purge gas is typically sufficient to remove the reaction by-products as well as any residual materials remaining in the process chamber.

After the tungsten nucleation layer is formed, the interconnect structure shown in FIG. 6C, may be filled with a bulk tungsten layer using either an ALD process or a CVD process. For the ALD process, the bulk tungsten layer may be formed according to the process parameters described above.

For the CVD process, the bulk tungsten (W) layer may be formed by thermally decomposing a W(F)₆ precursor. Carrier gases such as argon (Ar), and nitrogen (N₂), among others may be mixed with the W(F)₆ precursor.

In general, the following deposition process parameters can be used to form the bulk tungsten (W) layer in a deposition chamber similar to that shown in FIG. 4. The process parameters range from a wafer temperature of about 50° C. to about 850° C., a chamber pressure of about 0.5 torr to about 100 torr, a W(F)₆ precursor flow rate of about 1 sccm to about 10000 sccm, and a carrier gas flow rate of about 100 sccm to about 10000 sccm. The above process parameters provide a deposition rate for the tungsten (W) layer in a range of about 50 Å/min to about 4000 Å/min when implemented on a 200 mm (millimeter) substrate in a deposition chamber available from Applied Materials, Inc., located in Santa Clara, Calif.

Other deposition chambers are within the scope of the invention, and the parameters listed above may vary according to the particular deposition chamber used to form the tungsten (W) film. For example, other deposition chambers may have a larger (e.g., configured to accommodate 300 mm substrates) or smaller volume, requiring gas flow rates that are larger or smaller than those recited for deposition chambers available from Applied Materials, Inc.

Alternatively, the contact layer 506 may be an aluminum (Al) layer deposited using dimethyl aluminum hydride (DMAH), or other DMAH containing compounds, or a CVD copper layer deposited using Cu⁺²(hfac)₂ (copper hexafluoro acetylacetonate), Cu⁺²(fod)₂ (copper heptafluoro dimethyl octanediene), Cu⁺¹hfac TMVS (copper hexafluoro acetylacetonate trimethylvinylsilane), or combinations thereof.

In an alternate embodiment, a composite refractory metal nitride layer is formed. The composite refractory metal nitride layer comprises two or more refractory metals. The composite refractory metal nitride layer may be formed by sequentially chemisorbing monolayers of a nitrogen-containing compound and two or more refractory metal compounds onto a substrate as shown in FIGS. 8A-8C.

B. Capacitive Memory Device

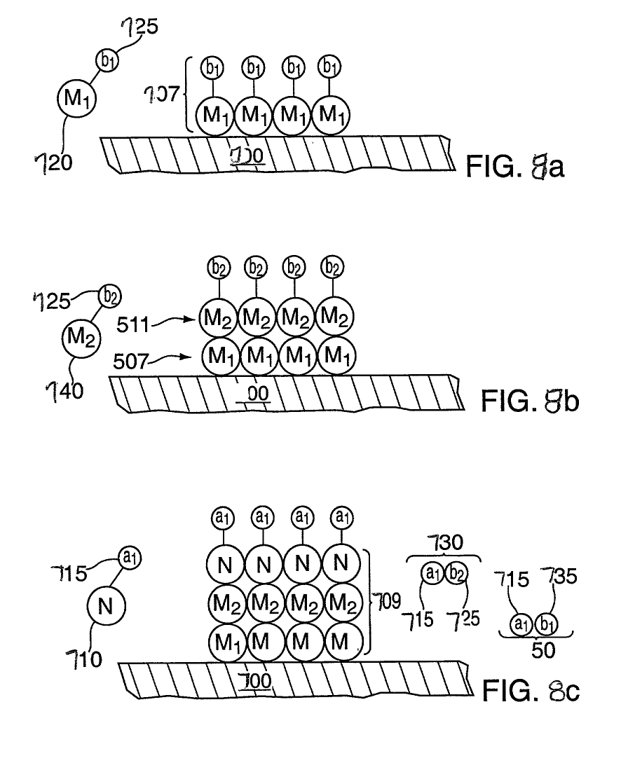

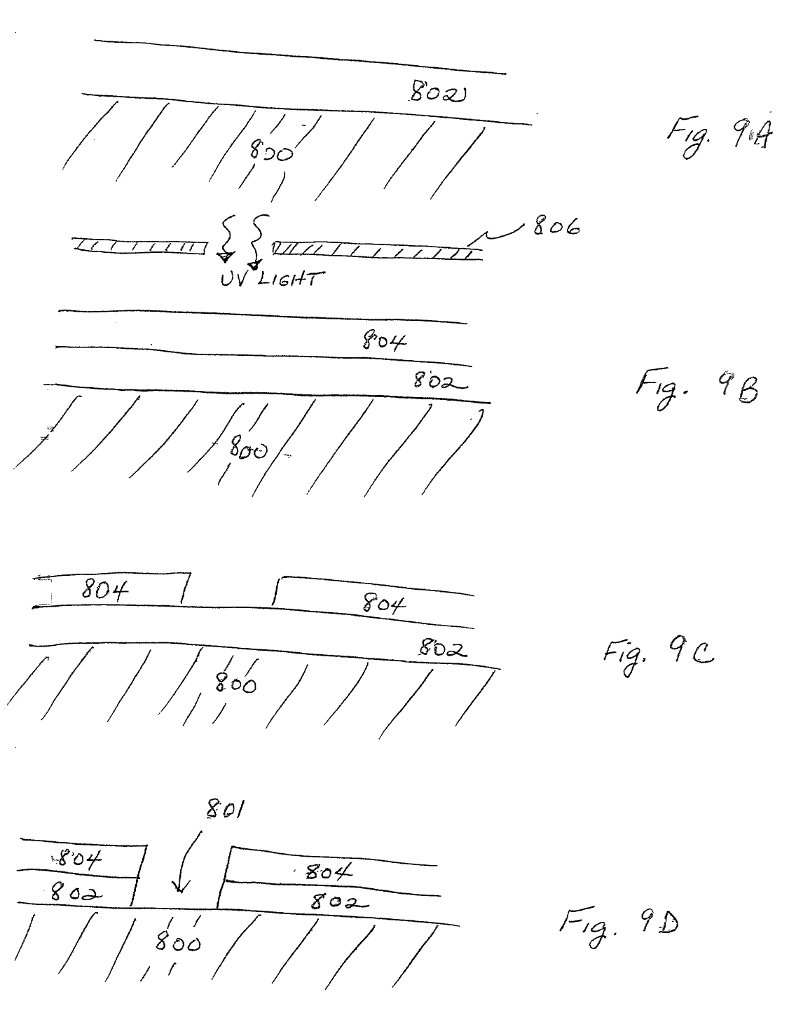

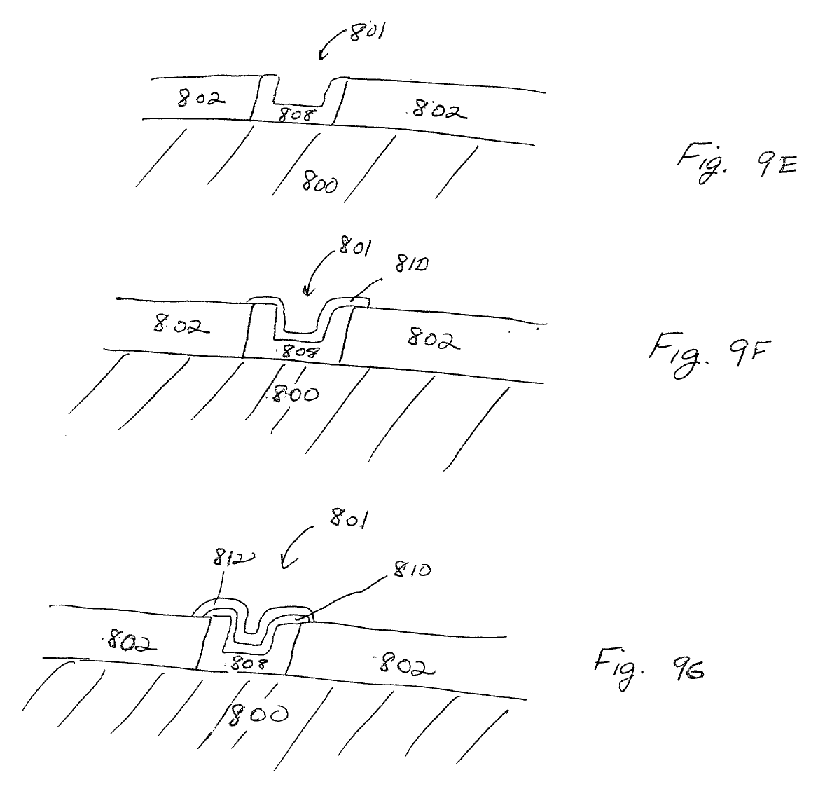

FIGS. 9A-9G illustrate schematic cross-sectional views of a substrate 800 at different stages of a capacitive memory cell fabrication sequence. Depending on the specific stage of processing, substrate 800 may correspond to a silicon wafer, or other material layer that has been formed on the silicon wafer. Alternatively, the substrate may have integrated circuit structures (not shown) such as logic gates formed on regions thereof.

FIG. 9A, for example, illustrates a cross-sectional view of a silicon substrate 800 having a material layer 802 formed thereon. The material layer 802 may be an oxide (e.g., fluorosilicate glass (FSG), undoped silicate glass (USG), organosilicates) or a silicon carbide material. Material layer 802 preferably has a low dielectric constant (e.g., dielectric constant less than about 5). The thickness of material layer 802 is variable depending on the size of the structure to be fabricated. Typically, material layer 802 has a thickness of about 1,000 Å to about 20,000 Å.

Referring to FIG. 9B, a layer of energy sensitive resist material 804 is formed on material layer 802. The layer of energy sensitive resist material 804 can be spin coated on the substrate to a thickness in a range of about 4,000 Å to about 10,000 Å. Most energy sensitive resist materials are sensitive to ultraviolet (UV) radiation having a wavelength less than about 500 nm (nanometers). Deep ultraviolet (DUV) resist materials are sensitive to UV radiation having wavelengths less than about 250 nm.

An image of a pattern is introduced into the layer of energy sensitive resist material 804 by exposing such energy sensitive resist material to UV radiation via mask 806. The image of the pattern introduced into the layer of energy sensitive resist material 804 is developed in an appropriate developer to define the pattern therethrough, as shown in FIG. 9C. Thereafter, referring to FIG. 9D, the pattern defined in the energy sensitive resist material 804 is transferred through material layer 802. The pattern is transferred through material layer 802 to form apertures 801 therein, using the energy sensitive resist material 804 as a mask. The pattern is transferred through material layer 802 using an appropriate chemical etchant.

The apertures 801 have widths less than about 0.5 μm (micrometer) wide and depths of about 0.5 μm to about 2 μm, providing aspect ratio structures in a range of greater than about 4:1.

Referring to FIG. 9E, a TiN bottom electrode 808 is conformably deposited along the sidewalls and bottom surface of aperture 801. The TiN bottom electrode 808 is conformably deposited using ALD techniques according to the process parameters described above with respect to FIGS. 7A-7D. The thickness of the TiN bottom electrode 808 is variable depending on the size of the structure to be fabricated. Typically, the TiN bottom electrode 808 has a thickness of about 1,000 Å to about 10,000 Å.

The TiN bottom electrode 808 is patterned and etched to remove unwanted electrode material from the substrate 800. The TiN bottom electrode is patterned using conventional lithography. The TiN bottom electrode is etched using a fluorocarbon compound such as carbon tetrafluoride (CF₄).

After the TiN bottom electrode 808 is deposited conformably in the apertures 301 and patterned, a Ta₂O₅ memory cell dielectric layer 810 is conformably deposited thereon, as shown in FIG. 8F The Ta₂O₅ memory cell dielectric layer 810 is conformably deposited using CVD techniques.

The Ta₂O₅ memory cell dielectric material may be formed from a reaction of a gas mixture comprising a Ta containing metal organic precursor and an oxidizing gas. The tantalum containing metal organic precursor may be selected, for example, from the group of tantalum ethyl oxide (TAETO) (Ta(OC₂H₅)₅), pentakis(diethylamido) tantalum (PDEAT) (Ta(NEt₂)₅), pentakis(ethylmethylamido) tantalum (PEMAT) (Ta(N (Et)(Me))₅), pentakis(dimethylamido) tantalum (PDMAT) (Ta(NMe₂)₅), tetrakis(ethylmethylamido) tantalum (TEMAT) (Ta(N(Et)(Me))₄), tetrakis(diethylamido) tantalum (TDEAT) (Ta(NEt₂)₄), tetrakis(dimethylamido) tantalum (TDMAT) (Ta(NMe₂)₄), among others.

Oxygen (O₂), nitrous oxide (N₂O), carbon monoxide (CO), carbon dioxide (CO₂), nitrogen (N₂) or combinations thereof, among others, may be used as the oxidizing gas.

In general the following deposition process parameters may be used to form the Ta₂O₅ memory cell dielectric in a process chamber similar to that shown in FIG. 4. The process parameters range from a wafer temperature of less than about 450° C., a chamber pressure of about 1 torr to about 30 torr, a tantalum containing metal organic precursor flow rate of about 50 sccm to about 7000 sccm, an oxidizing gas flow rate of about 500 sccm to about 1 slm, and a radio frequency (RF) power of about 5 watts/cm² to about 30 watts/cm². The above process parameters provide a deposition rate for the Ta₂O₅ memory cell dielectric of about 10 Å/min to about 500 Å/min.

The Ta₂O₅ memory cell dielectric may optionally be doped with aluminum oxide (Al₂O₃). An aluminum containing metal organic precursor such as, for example, dimethyl aluminum hydroxide (DMAH) (Me₂AlOH), aluminum ethyl oxide (ALETO) (Al(OC₂H₅)₃), and aluminum isopropyl oxide (Al(OC₃H₇)₃), among others, may be provided to the CVD deposition chamber when the Ta₂O₅ memory cell dielectric is to be doped with aluminum oxide (Al₂O₃). The aluminum containing metal organic precursor may be provided to the CVD deposition chamber at a flow rate of about 10 mgm to about 200 mgm.

The thickness of the Ta₂O₅ memory cell dielectric layer 810 is variable depending on the size of the structure to be fabricated. Typically, the Ta₂O₅ memory cell dielectric layer 810 has a thickness of about 100 Å to about 500 Å.

The Ta₂O₅ memory cell dielectric 810 is also patterned and etched to remove unwanted dielectric material from the substrate 800. The Ta₂O₅ dielectric material is patterned using conventional lithography. The Ta₂O₅ dielectric material is etched using a chorine compound such as tantalum pentachloride (TaCl₅).

Referring to FIG. 9G, the capacitive memory cell is completed by conformably depositing a TiN top electrode 812 on the patterned Ta₂O₅ memory cell dielectric layer 810. The TaN top electrode 812 is conformably deposited using ALD techniques according to the process parameters described above. The thickness of the TiN top electrode 812 is variable depending on the size of the structure to be fabricated. Typically, the TiN top electrode 812 has a thickness of about 1,000 Å to about 10,000 Å.

The TiN top electrode 812 is optionally patterned and etched to remove unwanted electrode material from the substrate 800. The TiN top electrode is patterned using conventional lithography. The TiN top electrode may be etched using a fluorocarbon compound such as carbon tetrafluoride (CF₄).

Although several preferred embodiments, which incorporate the teachings of the present invention have been shown and described in detail, those skilled in the art can readily devise many other varied embodiments that still incorporate these teachings.

What is claimed is:

1. A method of film deposition, comprising the step of:
(a) chemisorbing monolayers of a nitrogen-containing compound and one or more refractory metal compounds on a substrate to form a refractory metal nitride layer thereon.

2. The method of claim 1 wherein the substrate is subjected to a purge gas following chemisorption of each monolayer.

3. The method of claim 1 wherein the nitrogen-containing compound is selected from the group of ammonia (NH₃), hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), as well as combinations thereof.

4. The method of claim 1 wherein the one or more refractory metal compounds comprise a refractory metal selected from the group of titanium (Ti), tungsten (W), vanadium (V), niobium (Nb), tantalum (Ta), zirconium (Zr), hafnium (Hf), chromium (Cr), and molybdenum (Mo).

5. The method of claim 4 wherein the one or more refractory metal compounds are selected from the group of titanium tetrachloride (TiCl₄), tungsten hexafluoride (WF₆), tantalum pentachloride (TaCl₅), zirconium tetrachloride (ZrCl₄), hafnium tetrachloride (HfCl₄), molybdenum pentachloride (MOCl₅), niobium pentachloride (NbCl₅), vanadium pentachloride (VCl₅), chromium tetrachloride (CrCl₄), titanium iodide (Til₄), titanium bromide (TiBr₄), tetrakis(dimethylamido)titanium (TDMAT), pentakis(dimethylamido)tantalum (PDMAT), tetrakis(diethylamido)titanium (TDEAT), tungsten hexacarbonyl (W(CO)₆), tungsten hexachloride (WCl₆), tetrakisdiethylamido)titanium (TDEAT), pentakisdiethylamido)tantalum (PDEAT), and combinations thereof.

6. The method of claim 1 wherein step (a) is performed at a temperature between about 20° C. and about 600° C.

7. The method of claim 1 wherein step (a) is performed at a pressure less than about 100 torr.

8. The method of claim 2 wherein the purge gas is selected from the group of helium (He), argon (Ar), hydrogen (H₂), nitrogen (N₂), ammonia (NH₃), and combinations thereof.

9. The method of claim 1 wherein monolayers of the nitrogen-containing compound and the one or more refractory metal compounds are alternately chemisorbed on the substrate.

10. The method of claim 9 wherein one monolayer of the nitrogen-containing compound is chemisorbed on the substrate between each chemisorbed monolayer of the one or more refractory metal compounds.

11. The method of claim 10 wherein the monolayer of the nitrogen-containing compound is chemisorbed on the substrate prior to the one or more refractory compounds.

12. The method of claim 10 wherein one of the one or more refractory metal compounds is chemisorbed on the substrate prior to the nitrogen-containing compound.

13. The method of claim 9 wherein one monolayer of the nitrogen-containing compound is chemisorbed on the substrate after two or more monolayers of the one or more refractory metal compounds are chemisorbed thereon.

14. The method of claim 9 wherein two or more monolayers of the one or more refractory metal compounds are chemisorbed on the substrate after one monolayer of the nitrogen-containing compound is chemisorbed thereon.

15. A method of forming a barrier layer structure for use in integrated circuit fabrication, comprising the steps of:
(a) providing a substrate having an oxide layer thereon, wherein the oxide layer has apertures formed therein to a top surface of the substrate; and
(b) forming at least one refractory metal
nitride layer on at least portions of the substrate surface, wherein the at least one refractory metal nitride layer is formed using a sequential chemisorption process.

16. The method of claim 15 wherein the at least one refractory metal nitride layer comprises one or more refractory metals.

17. The method of claim 16 wherein the one or more refractory metals are selected from the group of titanium (Ti), tungsten (W), vanadium (V), niobium (Nb), tantalum (Ta), zirconium (Zr), hafnium (Hf), chromium (Cr), and molybdenum (Mo).

18. The method of claim 15 wherein the sequential chemisorption process of step (b) comprises the step of:
(c) chemisorbing monolayers of a nitrogen-containing compound and one or more refractory metal compounds on the substrate to form the refractory metal nitride layer thereon.

19. The method of claim 18 wherein the substrate is subjected to a purge gas following chemisorption of each monolayer.

20. The method of claim 18 wherein the nitrogen-containing compound is selected from the group of ammonia (NH₃), hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), as well as combinations thereof.

21. The method of claim 18 wherein the one or more refractory metal compounds are selected from the group of titanium tetrachloride (TiCl₄), tungsten hexafluoride (WF₆), tantalum pentachloride (TaCl₅), zirconium tetrachloride (ZrCl₄), hafnium tetrachloride (HfCl₄), molybdenum pentachloride (MoCl₅), niobium pentachloride (NbCl₅), vanadium pentachloride (VCl₅), chromium tetrachloride (CrCl₄), titanium iodide (Til₄), titanium bromide (TiBr₄), tetrakis(dimethylamido)titanium (TDMAT), pentakis(dimethylamido) tantalum (PDMAT), tetrakis(diethylamido)titanium (TDEAT), tungsten hexacarbonyl (W(CO)₆), tungsten hexachloride (WCl₆), tetrakisdiethylamido)titanium (TDEAT), pentakisdiethylamido)tantalum (PDEAT), and combinations thereof.

22. The method of claim 18 wherein step (c) is performed at a temperature between about 20° C. and about 600° C.

23. The method of claim 18 wherein step (c) is performed at a pressure less than about 100 torr.

24. The method of claim 19 wherein the purge gas is selected from the group of helium (He), argon (Ar), hydrogen (H₂), nitrogen (N₂), ammonia (NH₃), and combinations thereof.

25. The method of claim 18 wherein monolayers of the nitrogen-containing compound and the one or more refractory metal compounds are alternately chemisorbed on the substrate.

26. The method of claim 25 wherein one monolayer of the nitrogen-containing compound is chemisorbed on the substrate between each chemisorbed monolayer of the one or more refractory metal compounds.

27. The method of claim 26 wherein the nitrogen-containing compound is chemisorbed on the substrate prior to the one or more refractory compounds.

28. The method of claim 26 wherein one monolayer of the one or more refractory metal compounds is chemisorbed on the substrate prior to the monolayer of the nitrogen-containing compound.

29. The method of claim 25 wherein one monolayer of the nitrogen-containing compound is chemisorbed on the substrate after two or more monolayers of the one or more refractory metal compounds are chemisorbed thereon.

30. The method of claim 25 wherein two or more monolayers of the one or more refractory metal compounds are chemisorbed on the substrate after one monolayer of the nitrogen-containing compound is chemisorbed thereon.

31. A method of fabricating a device, comprising:
forming one or more memory cells on a substrate, wherein each memory cell includes two electrodes separated one from the other by a memory cell dielectric material, and wherein at least one of the two electrodes comprises a refractory metal nitride layer formed using a sequential chemisorption process.

32. The method of claim 31 wherein the refractory metal nitride layer comprises one or more refractory metals.

33. The method of claim 31 wherein the one or more refractory metals are selected from the group of titanium (Ti), tungsten (W), vanadium (V), niobium (Nb), tantalum (Ta), zirconium (Zr), hafnium (Hf), chromium (Cr), and molybdenum (Mo).

34. The method of claim 31 wherein the sequential chemisorption process of step (b) comprises the step of:
(c) chemisorbing monolayers of a nitrogen-containing compound and one or more refractory metal compounds on the substrate to form the refractory metal nitride layer thereon.

35. The method of claim 34 wherein the substrate is subjected to a purge gas following chemisorption of each monolayer.

36. The method of claim 34 wherein the nitrogen-containing compound is selected from the group of ammonia (NH₃), hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), as well as combinations thereof.

37. The method of claim 34 wherein the one or more refractory metal compounds are selected from the group of titanium tetrachloride (TiCl₄), tungsten hexafluoride (WF₆), tantalum pentachloride (TaCl₅), zirconium tetrachloride (ZrCl₄), hafnium tetrachloride (HfCl₄), molybdenum pentachloride (MoCl₅), niobium pentachloride (NbCl₅), vanadium pentachloride (VCl₅), chromium tetrachloride (CrCl₄), titanium iodide (Til₄), titanium bromide (TiBr₄), tetrakis(dimethylamido)titanium (TDMAT), pentakis(dimethylamido) tantalum (PDMAT), tetrakis(diethylamido)titanium (TDEAT), tungsten hexacarbonyl (W(CO)₆), tungsten hexachloride (WCl₆), tetrakisdiethylamido)titanium (TDEAT), pentakisdiethylamido)tantalum (PDEAT), and combinations thereof.

38. The method of claim 34 wherein step (c) is performed at a temperature between about 20° C. and about 600° C.

39. The method of claim 34 wherein step (c) is performed at a pressure less than about 100 torr.

40. The method of claim 35 wherein the purge gas is selected from the group of helium (He), argon (Ar), hydrogen (H₂), nitrogen (N₂), ammonia (NH₃), and combinations thereof.

41. The method of claim 34 wherein monolayers of the nitrogen-containing compound and the one or more refractory metal compounds are alternately chemisorbed on the substrate.

42. The method of claim 41 wherein one monolayer of the nitrogen-containing compound is chemisorbed on the substrate between each chemisorbed monolayer of the one or more refractory metal compounds.

43. The method of claim 41 wherein the nitrogen-containing compound is chemisorbed on the substrate prior to the one or more refractory compounds.

44. The method of claim 41 wherein one monolayer of the one or more refractory metal compounds is chemisorbed on the substrate prior to the monolayer of the nitrogen-containing compound.

45. The method of claim 41 wherein one monolayer of the nitrogen-containing compound is chemisorbed on the substrate after two or more monolayers of the one or more refractory metal compounds are chemisorbed thereon.

46. The method of claim 41 wherein two or more monolayers of the one or more refractory metal compounds are chemisorbed on the substrate after one monolayer of the nitrogen-containing compound is chemisorbed.

47. The method of claim 31 wherein the memory cell dielectric material is an oxide.

48. The method of claim 47 wherein the oxide is tantalum pentoxide (Ta₂O₅).

49. The method of claim 48 wherein the Ta₂O₅ is formed on the substrate by
positioning the substrate in a deposition chamber;
providing a gas mixture to the deposition chamber, wherein the gas mixture comprises a tantalum containing metal organic precursor and an oxidizing gas; and
reacting the gas mixture in the presence of an electric field to form Ta₂O₅ on the substrate.

50. The method of claim 48 wherein the Ta₂O₅ is doped with aluminum oxide (Al₂O₃).

51. The method of claim 49 wherein the gas mixture further comprises an aluminum containing metal organic precursor.

52. A computer storage medium containing a software routine that, when executed, causes a general purpose computer to control a deposition chamber using a method of thin film deposition comprising the step of:
(a) forming a refractory metal nitride layer on a substrate, wherein the refractory metal nitride layer is formed using a sequential chemisorption process.

53. The computer storage medium of claim 52 wherein the at least one refractory metal nitride layer comprises one or more refractory metals.

54. The computer storage medium of claim 53 wherein the one or more refractory metals are selected from the group of titanium (Ti), tungsten (W), vanadium (V), niobium (Nb), tantalum (Ta), zirconium (Zr), hafnium (Hf), chromium (Cr), and molybdenum (Mo).

55. The computer storage medium of claim 52 wherein the sequential chemisorption process of step (a) comprises the step of:
(b) chemisorbing monolayers of a nitrogen-containing compound and one or more refractory metal compounds on the substrate to form the refractory metal nitride layer thereon.

56. The computer storage medium of claim 55 wherein the substrate is subjected to a purge gas following chemisorption of each monolayer.

57. The computer storage medium of claim 55 wherein the nitrogen-containing compound is selected from the group of ammonia (NH₃), hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), as well as combinations thereof.

58. The computer storage medium of claim 55 wherein the one or more refractory metal compounds are selected from the group of titanium tetrachloride (TiCl₄), tungsten hexafluoride (WF₆), tantalum pentachloride (TaCl₅), zirconium tetrachloride (ZrCl₄), hafnium tetrachloride (HfCl₄), molybdenum pentachloride (MoCl₅), niobium pentachloride (NbCl₅), vanadium pentachloride (VCl₅), chromium tetrachloride (CrCl₄), titanium iodide (Til₄), titanium bromide (TiBr₄), tetrakis(dimethylamido)titanium (TDMAT), pentakis(dimethylamido) tantalum (PDMAT), tetrakis(diethylamido)titanium (TDEAT), tungsten hexacarbonyl (W(CO)₆), tungsten hexachloride (WCl₆), tetrakisdiethylamido)titanium (TDEAT), pentakisdiethylamido)tantalum (PDEAT), and combinations thereof.

59. The computer storage medium of claim 55 wherein step (b) is performed at a temperature between about 20° C. and about 600° C.

60. The computer storage medium of claim 55 wherein step (b) is performed at a pressure less than about 100 torr.

61. The computer storage medium of claim 56 wherein the purge gas is selected from the group of helium (He), argon (Ar), hydrogen (H₂), nitrogen (N₂), ammonia (NH₃), and combinations thereof.

62. The computer storage medium of claim 55 wherein monolayers of the nitrogen-containing compound and the one or more refractory metal compounds are alternately chemisorbed on the substrate.

63. The computer storage medium of claim 62 wherein one monolayer of the nitrogen-containing compound is chemisorbed on the substrate between each chemisorbed monolayer of the one or more refractory metal compounds.

64. The computer storage medium of claim 62 wherein the nitrogen-containing compound is chemisorbed on the substrate prior to the one or more refractory metal compounds.

65. The computer storage medium of claim 62 wherein one of the one or more refractory metal compounds is chemisorbed on the substrate prior to the nitrogen-containing compound.

66. The computer storage medium of claim 62 wherein one monolayer of the nitrogen-containing compound is chemisorbed on the substrate after two or more monolayers of the one or more refractory metal compounds are chemisorbed thereon.

67. The computer storage medium of claim 62 wherein two or more monolayers of the one or more refractory metal compounds are chemisorbed on the substrate after one monolayer of the nitrogen-containing compound is chemisorbed thereon.

68. A device comprising:
at least one refractory metal nitride layer formed on a substrate, wherein one of the at least one refractory metal nitride layers comprises two or more refractory metals.

69. The device of claim 68 wherein the two or more refractory metals are selected from the group of titanium (Ti), tungsten (W), vanadium (V), niobium (Nb), tantalum (Ta), zirconium (Zr), hafnium (Hf), chromium (Cr), and molybdenum (Mo).

70. A device comprising:
a substrate having an oxide layer thereon, wherein the oxide layer has an aperture formed therein to a top surface of the substrate; and
at least one refractory metal nitride layer formed on portions of the oxide layer and the substrate surface, wherein one of the at least one refractory metal nitride layers comprises two or more refractory metals.

71. The device of claim 70 wherein the two or more refractory metals are selected from the group of titanium (Ti), tungsten (W), vanadium (V), niobium (Ni), tantalum (Ta), zirconium (Zr), hafnium (Hf), chromium (Cr), and molybdenum (Mo).

72. An interconnect structure, comprising:
a substrate having an oxide layer thereon, wherein the oxide layer has apertures formed therein to a top surface of the substrate;
a first refractory metal nitride layer formed on portions of the oxide layer and the substrate surface, wherein the first refractory metal nitride layer comprises one or more refractory metals; and
a second refractory metal nitride layer formed on the first refractory metal nitride layer, wherein the second refractory metal nitride layer comprises one or more refractory metals.

73. The interconnect structure of claim 72 wherein the one or more refractory metals are selected from the group of titanium (Ti), tungsten (W), vanadium (V), niobium (Nb), tantalum (Ta), zirconium (Zr), hafnium (Hf), chromium (Cr), and molybdenum (Mo).

74. The interconnect structure of claim 72 wherein the first refractory metal nitride layer has a thickness less than about 100 Å (Angstroms).

75. The interconnect structure of claim 72 wherein the second refractory metal nitride layer has a thickness in a range of about 100 Å to about 1000 Å.

76. A memory cell device, comprising:
one or more memory cells on a substrate, wherein each memory cell includes two electrodes separated one from the other by a memory cell dielectric material, and wherein at least one of the two electrodes is a refractory metal nitride layer comprised of two or more refractory metals.

77. The device of claim 76 wherein the two or more refractory metals are selected from the group of titanium (Ti), tungsten (W), vanadium (V), niobium (Ni), tantalum (Ta), zirconium (Zr), hafnium (Hf), chromium (Cr), and molybdenum (Mo).
